(19) United States
(12) Patent Application Publication
(10) Pub. No.: US 2003/0025190 A1
(43) Pub. Date: Feb. 6, 2003

(54) Tape ball grid array semiconductor chip package having ball land pad isolated from adhesive, a method of manufacturing the same and a multi-chip package

(76) Inventors: Hyung Jik Byun, Cheonan-city (KR); Jin Ho Kim, Cheonan-city (KR)

Correspondence Address: LEE & STERBA, P.C., Suite 2000, 1101 Wilson Boulevard, Arlington, VA, 22209, US

(21) Appl. No.: 10/186,617

(22) Filed: Jul. 2, 2002

(30) Foreign Application Priority Data
Aug. 6, 2001 (KR) 2001-47266

(51) Int. Cl. H01L 23/48

(52) U.S. Cl. 257/690

(57) ABSTRACT

A tape ball grid array (TBGA) package having improved thermal reliability includes a semiconductor chip mounted on a tape circuit board having a base film, ball land pads, and board junction pads, wherein the semiconductor chip is attached to a first surface of the base film, the ball land pads are formed on an opposite, second surface of the base film, and the board junction pads are formed on either side of the base film. Each one of the board junction pads is electrically connected to a corresponding ball land pad using routings and/or via holes and to an associated chip pad by a bonding wire. A package body is formed by encapsulating the assembly, and external contact terminals, each one being attached to one of the ball land pads.

### BACKGROUND OF THE INVENTION

1. Field of the Invention

The present invention relates to a semiconductor package and a method of manufacturing the same. More particularly, the present invention relates to a tape ball grid array (TBGA) package using a tape circuit board as a chip mounting means and using a ball attached to the tape circuit board as an external contact terminal, a method of manufacturing the same, and a multi-chip package.

2. Description of the Related Art

Current trends toward smaller size, lighter weight, higher speed, higher performance, and higher density integrated circuits (ICs) require smaller and higher performance semiconductor packages. Accordingly, several minimum-sized packages have been developed to house these smaller ICs, such as a fine pitch ball grid array (FBGA) package, a chip scale package (CSP), a micro ball grid array (μBGA) package, and a tape ball grid array (TBGA) package. These packages have a variety of structures, but generally all use a plurality of solder balls to mount the IC package to a mounting substrate, such as an external printed circuit board.

FIG. 1 illustrates a cross-sectional view of a conventional TBGA package 110. As shown in FIG. 1, the chip size of such a TBGA package 110 is about 70-90% of a total package size, with a semiconductor chip 111 being mounted on a first surface of a tape circuit board 120, and a plurality of solder balls 139 being formed on a second surface of the tape circuit board 120. The second surface is opposite to the first surface, on which the semiconductor chip is mounted. The plurality of solder balls 139 act as external contact terminals to tape circuit board 120. Tape circuit board 120 includes a base film 121, a plurality of ball land pads 124, and a plurality of board junction pads 122. Ball land pads 124 are formed within a chip mounting area of the base film 121 wherein the semiconductor chip 111 is attached. The plurality of board junction pads 122 are formed beyond the chip mounting area.

The semiconductor chip 111 is typically attached to the chip mounting area using a dielectric adhesive 131, such as a liquid epoxy. Each one of the board junction pads 122 and an associated chip pad 112 of the semiconductor chip 111 are wire-bonded together using a bonding wire 135. Each board junction pad 122 and corresponding ball land pad 124 are connected to each other by a circuit routing (not shown). Thus, the semiconductor chip 111 and the solder balls 139 are electrically connected. After wire bonding, the electrical conjunction portions on the base film 121 are encapsulated in a package body 137, to protect the elements from the external environment.

Due to the use of the tape circuit board 120, the conventional TBGA package 110 has a size advantage as a general BGA package over a conventional printed circuit board (PCB). However, such a TBGA package 110 exhibits significant mechanical and electrical problems. In particular, tape swelling and/or void generation in the solder balls can create open circuits at the point where adhesive 131 and the ball land pad 124 are in direct contact. A crack generated due to moisture condensation in the void during an increased temperature condition, such as a temperature cycle test (T/C test) or an IR reflow, may be expanded to relatively weak points, i.e., the contact surface of adhesive 131 and ball land pad 124, and possibly to an opening 126, which is formed for attachment of solder ball 139. Due to variations of the conjunction conditions of the solder ball 139 and the ball land pad 124, the package becomes less reliable.

### SUMMARY OF THE INVENTION

According to a feature of an embodiment of the present invention, there are provided a TBGA package, a method of manufacturing the same, and a multi-chip package capable of preventing solder ball void generation, tape circuit board swelling, and improving package reliability in the event that a crack is generated by a void.

According to an aspect of an embodiment of the present invention, a TBGA package is provided that includes a semiconductor chip on which a plurality of chip pads are formed, a tape circuit board having a base film, a plurality of ball land pads, and a plurality of board junction pads. The semiconductor chip is attached to a first surface of the base film in a chip mounting region using an adhesive. In an embodiment of the present invention, the plurality of ball land pads are formed within the chip mounting region on a second surface of the base film, and the plurality of board junction pads are formed beyond the chip mounting area and electrically connected to the associated ball land pads by a unique one of a plurality of circuit routing means. One of a plurality of bonding wires electrically connects each chip pad with an associated board junction pad. Finally, a package body is formed over the tape circuit board by encapsulating the semiconductor chip, the plurality of bonding wires, and conjunction portions of the bonding wire to protect the assembly from the external environment, and an external contact terminal is attached to each one of the ball land pads.

The board junction pads may be formed on either side of the base film. If the board junction pads are formed on the opposite side of the base film from the plurality of ball land pads, each chip pad and a corresponding board junction pad are wire-bonded through a conductive through hole penetrating the base film. However, if the board junction pads are formed on the side of the base film to which the semiconductor chip is attached, each board junction pad and an associated ball pad may be electrically connected by a via hole formed in the base film, and each chip pad and a corresponding board junction pad are wire-bonded directly. A solder ball may be used as the external contact terminal. Additionally, forming a solder resist layer isolating the tape circuit board from the external environment is preferable.

According to another aspect of an embodiment of the present invention, a method for manufacturing a TBGA package is provided which includes (a) providing a tape circuit board having a base film having a first and a second surface, a plurality of ball land pads, and a plurality of board junction pads, wherein the ball land pads are formed on the second surface and the board junction pads are electrically connected to an associated one of the plurality of ball land pads. On the first surface of the base film, (b) mounting a semiconductor chip having a plurality of chip pads using an adhesive, (c) wire bonding each one of the plurality of chip pads to an associated one of the board junction pads using a bonding wire, (d) forming a package body on the tape circuit board by encapsulating the semiconductor chip, the bonding wire, and conjunction portions of the bonding wire, and (e) forming an external contact terminal on the ball land pad.

Preferably, a protective film may be temporarily attached to the side of the base film on which the ball land pads are formed (i.e., the second surface) before the formation of the package body, and the protective film may be eliminated after the formation of the package body. Such a protective film prevents a molding resin from being formed on unnecessary portions of the assembly.

According to another aspect of an embodiment of the present invention, a multi-chip package is provided that includes a tape circuit board having a base film, a plurality of ball land pads, and a plurality of board junction pads, wherein a chip mounting area is located on a first side of the base film and the board junction pads are electrically connected to an associated one of the ball land pads by a circuit routing means. The ball land pads are formed on the second side of the base film, preferably, within the chip mounting area. Preferably, a first semiconductor chip is mounted on the first surface of the base film within the chip mounting area using an adhesive, a second semiconductor chip is mounted on the first semiconductor chip using an adhesive, and a plurality of bonding wires are electrically connected between the first and second semiconductor chips and corresponding board junction pads. A protective package body encapsulates the first and second semiconductor chips, the plurality of bonding wires, and the conjunction portions of the bonding wires to protect the elements from the external environment. Finally, a plurality of external contact terminals are formed, each one being on a corresponding ball land pad.

These and other features and aspects of the present invention will be readily apparent to those of ordinary skill in the art upon review of the detailed description that follows.

### BRIEF DESCRIPTION OF THE DRAWINGS

FIG. 1 illustrates a cross-sectional view of a conventional semiconductor chip package.

FIG. 2 illustrates a cross-sectional view of a TBGA semiconductor chip package according to an embodiment of the present invention.

FIGS. 3a and 3b illustrate top views of the second surface of the tape circuit board of a TBGA package, at subsequent stages in the manufacture of the embodiment of FIG. 2.

FIGS. 4 illustrates a top view of the first surface of the tape circuit board and FIGS. 5-6 illustrate cross-sectional views of a manufacturing process of a TBGA package according to the embodiment of FIG. 2.

FIG. 7 illustrates a cross-sectional view of a semiconductor chip package according to another embodiment of the present invention.

FIG. 8 illustrates a cross-sectional view of a multi-chip package according to an embodiment of the present invention.

### DETAILED DESCRIPTION OF THE INVENTION

Korean Patent Application No. 2001-47266, filed on Aug. 6, 2001, and entitled: “Tape Ball Grid Array Semiconductor Chip Package Having Ball Land Pad Isolated from Adhesive and Manufacturing Method Thereof and a Multi-chip Package,” is incorporated by reference herein in its entirety.

The present invention will now be described more fully hereinafter with reference to the accompanying drawings, in which preferred embodiments of the invention are shown. The present invention may, however, be modified in different forms and should not be construed as being limited to the embodiments set forth herein. Rather, these embodiments are provided so that this disclosure will be thorough and complete, and will fully convey the scope of the invention to those of ordinary skill in the art. In the drawings, like reference numbers refer to like elements throughout.

FIG. 2 illustrates a cross-sectional view of a first embodiment of a tape ball grid array (TBGA) package 10 according to the present invention, wherein a semiconductor chip 11 having a plurality of chip pads 12, formed on an upper side thereof, is mounted on an upper side (i.e., a first surface) of a tape circuit board 20. On an opposing lower side (i.e., a second surface) of tape circuit board 20 are attached a plurality of solder balls 39 as external contact terminals.

Tape circuit board 20 further includes a plurality of ball land pads 24 and a plurality of board junction pads 22 deposited on a base film 21 as seen in the view of FIG. 2. The plurality of ball land pads 24 are formed within a chip mounting area for semiconductor chip 11, while the plurality of board junction pads 22 are formed around the periphery of the mounting area and ball land pads 24. Each one of the ball land pads 24 are connected to associated board junction pads 22 by a circuit routing means (not shown). A portion of each one of the board junction pads 22 is exposed upward through a through hole 25, which penetrates base film 21. The base film 21 is preferably made of a polyimide material, whereas the ball land pads 22 and the board junction pads 24 are preferably made of high conductivity metal, such as copper.

Semiconductor chip 11 is preferably attached to the first surface of base film 21 using an adhesive 31, such as an Ag-epoxy. The plurality of chip pads 12 of the semiconductor chip 11 may be either an edge-type or center-type pad. As shown in FIG. 2, the edge-type pad is preferably used in order to reduce the length of a bonding wire.

Semiconductor chip 11 and tape circuit board 20 are electrically connected by a plurality of wire-bonding wires 35 between each chip pad 12 and an associated board junction pad 22. Each bonding wire 35 passes through a through hole 25.

To protect the electrical connections from the external environment, a package body 37 is used to encapsulate the semiconductor chip 11, the plurality of bonding wires 35, and conjunction portions of each bonding wire 35 on the first surface of tape circuit board 20. A solder resist layer 27 is preferably formed on the second surface of the base film 21 to isolate tape circuit board 20 from the external environment, and to insulate the plurality of board junction pads 22. Each one of the plurality of solder balls 39 is attached to a corresponding ball land pad 24 in the exposed portions of the solder resist layer 27.

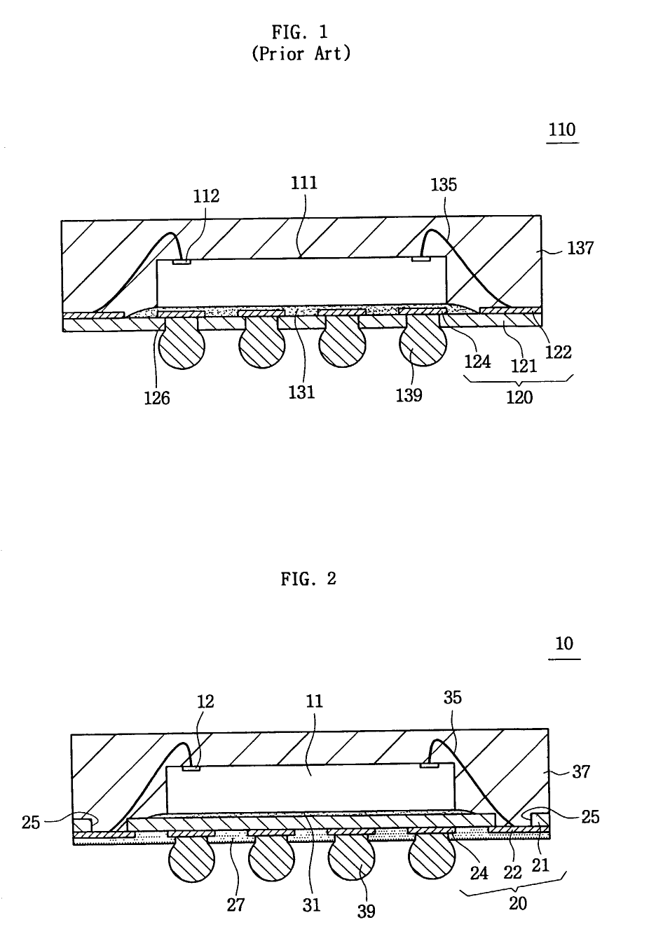

According to the aforementioned TBGA package 10, because the ball land pads 24 are preferably formed on an opposite side of a base film 21 from the mounting surface for semiconductor chip 11, adhesive 31 is not directly in contact with ball land pad 24. Thus, openings (126 of FIG. 1) through the chip mounting area for ball attachment are unnecessary. Even if a void occurs in the adhesive and expands to create a crack, there would be no effect on the connections between ball land pad 24 and solder ball 39. Further, because openings for ball attachment are not needed and a tape circuit board 20 is attached to solder balls 39, tape circuit board 20 may provide a buffer from thermal expansions and contractions in materials having different thermal expansion coefficients. Further, since the aforementioned structure is stable under high temperature conditions, TBGA package 10 may be mounted to an external board using a soldering material, such as SnAg having a melting point above 240° C., instead of a lower-temperature soldering material that includes a lead (Pb) ingredient, which is detrimental to the environment. Additionally, because openings in base film 21 for connecting ball land pads with solder balls are not needed, the structure of this embodiment is also suitable for a fine pitch design.

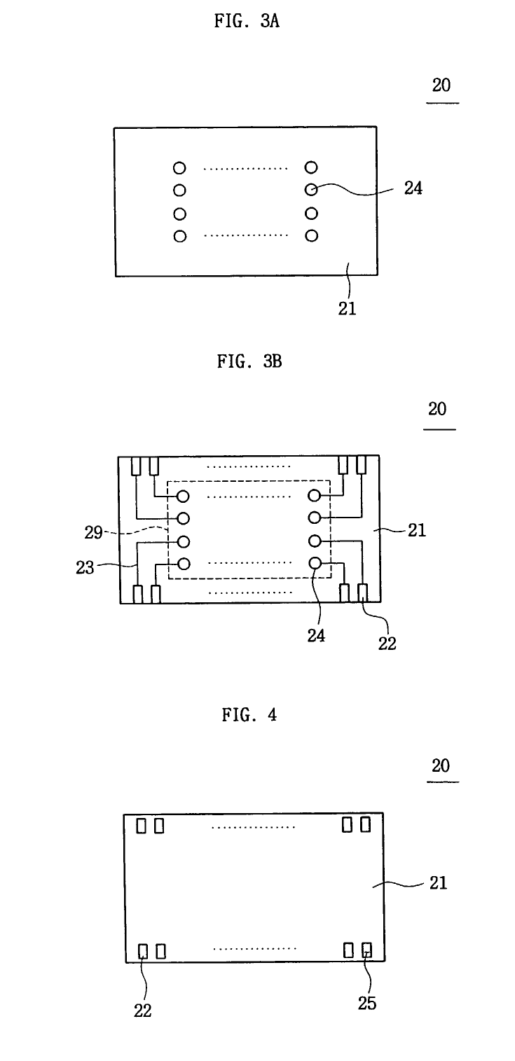

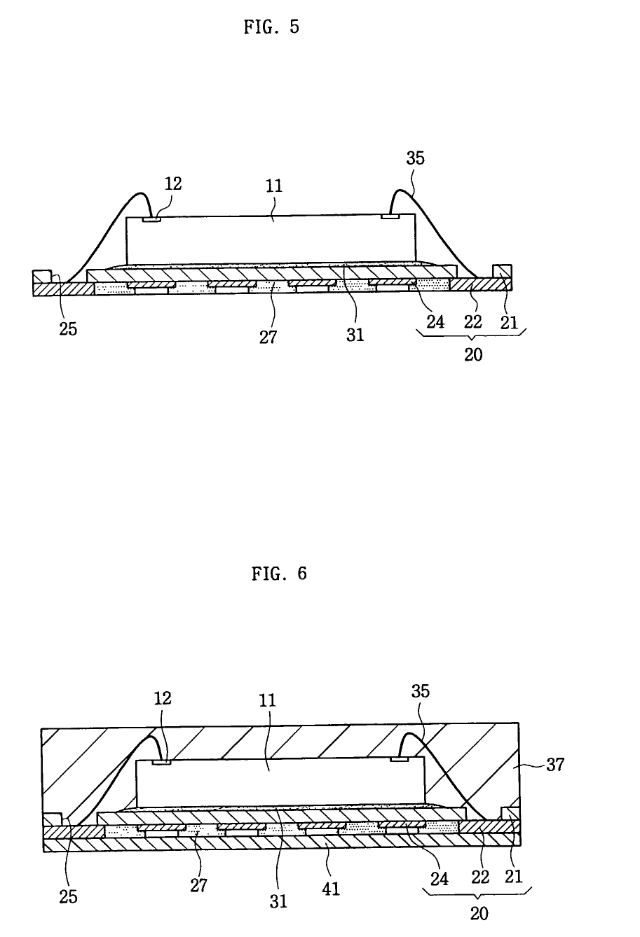

Preferred steps used to manufacture the first embodiment of the TBGA package shown in FIG. 2 will now be described with respect to FIGS. 3a through 6, wherein FIGS. 3a and 3b illustrate top views of the second surface of a tape circuit board and FIGS. 4-6 illustrate a top view of the first surface, a cross-sectional view of the TBGA package with the tape circuit board attached and a cross-sectional view of the TBGA package with the tape circuit board attached, respectively.

Referring to FIGS. 3a and 3b, in a first step, a plurality of ball land pads 24 are formed in a chip mounting area 29 on a second surface of a base film 21, and a plurality of board junction pads 22 are formed outside of the chip mounting area 29 also on the second surface of base film 21, with a plurality of interconnecting electrical conductors 23 therebetween. This step may additionally include the steps of: 1a) depositing a thin layer of copper material on the second surface of the base film 21, and 1b) etching the thin layer to form the plurality of ball land pads 24, the plurality of board junction pads 22, and a plurality of circuit routing conductors 23.

In a second step, as shown in FIG. 4, a plurality of through holes 25 penetrating the base film 21 are formed, with one through hole 25 being aligned over each board junction pad 22, thereby exposing each one of the plurality of the board junction pads 22 for subsequent wire bonding attachment. Punching and laser processes may be used to form the plurality of through holes 25. In a third step, a solder resist layer 27, as shown in FIG. 2, is formed on the second surface of base film 21 preferably using deposition. A photo solder resist (PSR) may be used as the solder resist.

In a fourth step, as shown FIG. 5, a semiconductor chip 11 a having a plurality of chip pads 12 is mounted on a first surface of base film 21 using an adhesive 31, such as Ag-epoxy, which is preferably deposited. The semiconductor chip 11 is preferably attached by heat pressure compression so that the plurality of chip pads 12 are arranged away from the TBGA package. In a fifth step, a wire bonding operation is performed to connect each chip pad 12 to an associated board junction pad 22 using a bonding wire 35. In a sixth step, a ball bonding operation is performed to attach one end of each bonding wire 35 to the chip pad 12. In a seventh step, a stitch bonding operation is performed to attach the other end of bonding wire 35 to the associated board junction pad 22.

In an eighth step, as shown in FIG. 6, a temporary protective film 41 is deposited on the second surface of the base film 21. This film provides protection from a potential problem wherein, in a subsequent encapsulation step, an epoxy molding resin may flow from the first surface of base film 21 to the second surface of base film 21.

In a ninth step, a package body 37 is formed on the tape circuit board 20 by encapsulating the semiconductor chip 11, the plurality of bonding wires 35, and the two conjunction portions of the plurality of bonding wires 35. After the encapsulation is completed, protective film 41 is preferably removed. In a final step, a plurality of solder balls 39 are attached to the plurality of ball land pads 24 to function as external contact terminals, as illustrated by FIG. 2.

It should be noted that the plurality of board junction pads 22 may be formed in a separate step than that used to form the plurality of ball land pads 24, and may be formed on either the first or second surfaces of base film 21 as long as appropriate interconnecting conductors 23 and corresponding via holes are formed, as will become evident in the following discussions of alternative embodiments of the present invention.

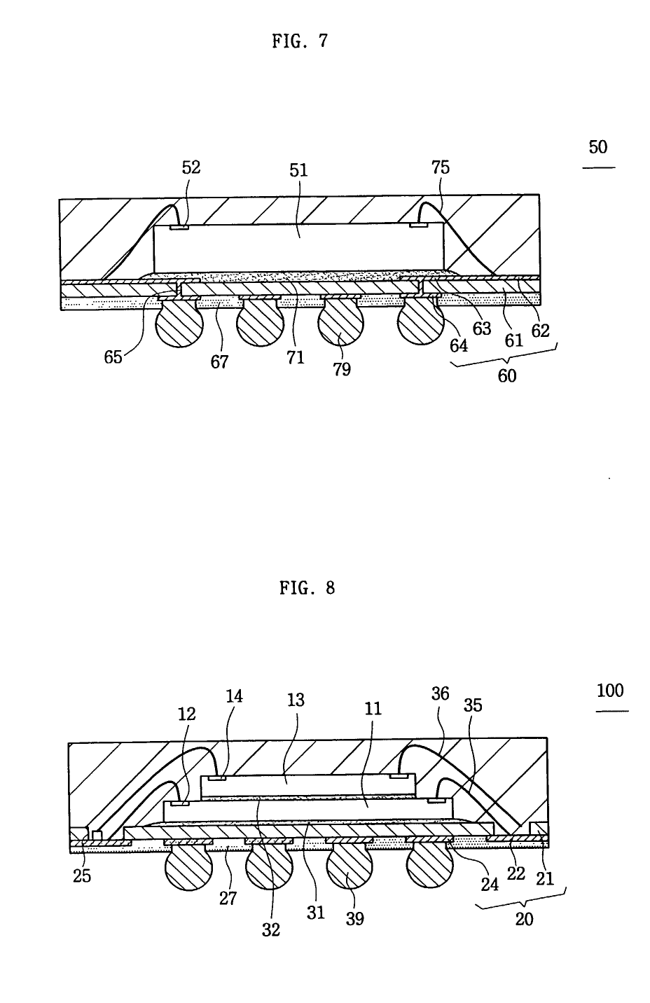

FIG. 7 illustrates a cross-sectional view of a second embodiment of a TBGA package according to the present invention. In a TBGA package 50 as shown in FIG. 7, similar to the first embodiment, a ball land pad 64 is formed on a second surface of a base film 61 of a tape circuit board 60, and a semiconductor chip 51 is attached to a first surface of a base film 61. A plurality of circuit routing conductors 63 and a plurality of board junction pads 62 are formed on the first surface of the base film 61. The plurality of board junction pads 62 and an associated one of the plurality of chip pads 52 are connected to each other by one of the plurality of bonding wires 75, and each one of the ball land pads 64 and the board junction pads 62 are electrically connected using a plurality of via holes 65. A solder resist layer 67 may be formed on the second surface of the base film 61 in order to prevent possible crack expansions at ball land pads 64, since an adhesive 71 is used to isolate ball land pads 64 from the base film 61 in a manner similar to that of the first embodiment. Further, a solder ball 79 is formed on a corresponding ball land pad 64.

FIG. 8 illustrates a cross-sectional view of a multi-chip package 100 according to a third embodiment of the present invention. The multi-chip package 100 preferably includes a first semiconductor chip 11 and a second semiconductor chip 13. The first semiconductor chip 11 is mounted on a first surface of tape circuit board 20 using adhesive 31, and the second semiconductor chip 13 is mounted on the first semiconductor chip 11 using adhesive 32. A plurality of ball land pads 24 are formed on a second surface of a base film 21, which is opposite to the first surface on which the first and second semiconductor chip 11 and 13 are mounted. A plurality of chip pads 12 and 14 of the first and second semiconductor chips 1 1 and 13, respectively, are connected to the plurality of board junction pads 22 using a plurality of bonding wires 35 and 36, either directly or through through holes 25 passing through the base film 21, depending on whether the board junction pads are formed on the first surface or the second surface, respectively.

According to the present invention, because the adhesive is isolated from the ball land pads, expansion of a crack due to moisture condensation in a void of the ball land pad is prevented. Therefore, package reliability is significantly improved since poor electrical connection problems, such as those resulting from ball opens and/or tape swelling, may be prevented. Also, the embodiments of the present invention exhibit high temperature reliability and may be used in fine pitch designs.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A tape ball grid array package, comprising:
a semiconductor chip having a plurality of chip pads formed thereon;
a tape circuit board including a base film, a plurality of ball land pads, and a plurality of board junction pads, wherein the semiconductor chip is attached to a first surface of the base film using an adhesive, the plurality of ball land pads are formed on a second surface of the base film, and each one of the plurality of board junction pads are electrically connected to an associated one of the plurality of ball land pads by a circuit routing means;
a plurality of bonding wires, each one electrically connecting a unique one of the plurality of chip pads to an associated one of the plurality of board junction pads;
a package body formed on the tape circuit board by encapsulating the semiconductor chip, the plurality of bonding wires, and the plurality of conjunction portions of the bonding wire; and
a plurality of external contact terminals, each one being attached to one of the plurality of ball land pads.

2. The tape ball grid array package as claimed in claim 1, wherein the plurality of board junction pads are formed on the second surface of the base film in an area outside of a chip mounting area; and
a plurality of through holes for exposing predetermined portions of the plurality of board junction pads are formed through the base film, wherein each one of the plurality of chip pads and an associated one of the plurality of board junction pads are wire-bonded together through an associated through hole.

3. The tape ball grid array package as claimed in claim 1, wherein the plurality of board junction pads are formed on the first surface of the base film, and a plurality of via holes for electrically connecting one of the plurality of board junction pads and a corresponding one of the plurality of ball land pads are formed through the base film.

4. The tape ball grid array package as claimed in claim 1, wherein the plurality of ball land pads are formed within the chip mounting area.

5. The tape ball grid array package as claimed in claim 1, wherein the plurality of ball land pads are isolated from the adhesive by the base film.

6. The tape ball grid array package as claimed in claim 1, wherein each one of the plurality of external contact terminals is a solder ball.

7. The tape ball grid array package as claimed in claim 1, wherein a solder resist layer is formed on the second surface of the base film.

8. The tape ball grid array package as claimed in claim 1, wherein the semiconductor chip is attached so that the plurality of chip pads formed on the semiconductor chip are away from the tape circuit board.

9. A method for manufacturing a tape ball grid array package, comprising:
a) providing a tape circuit board having a base film having a first and a second surface, a plurality of ball land pads and a plurality of board junction pads, wherein the plurality of ball land pads are formed on the second surface of the base film, and the plurality of board junction pads are electrically connected to an associated one of the plurality of ball land pads;
b) mounting a semiconductor chip, on which a plurality of chip pads are formed, on the first surface of the base film using an adhesive;
c) wire bonding each one of the plurality of chip pads to a corresponding one of the plurality of board junction pads by one of a plurality of bonding wires;
d) forming a package body on the tape circuit board by encapsulating the semiconductor chip, the bonding wires, and conjunction portions of the bonding wires; and
e) forming an external contact terminal to the ball land pad.

10. The method as claimed in claim 9, wherein a protective film is attached to the second surface of the base film before the formation of a package body, and the protective film is removed after the formation of the package body.

11. The method as claimed in claim 9, wherein (a) comprises:
(a1) forming the plurality of ball land pads within the chip mounting area and on the second surface of the base film and forming the plurality of board junction pads on the second surface of the base film in an area outside of the chip mounting area; and
(a2) forming a plurality of through holes, each one exposing one of the plurality of board junction pads by penetrating the base film.

12. The method as claimed in claim 11, wherein the plurality of through holes are formed by an etching process.

13. The method as claimed in claim 9, wherein (a) comprises:
(a1) forming the plurality of ball land pads within the chip mounting area and on the second surface of the base film, and forming a circuit routing means and the plurality of board junction pads on the first surface of the base film; and
(a2) forming a plurality of via holes for connecting each one of the plurality of ball land pads with a corresponding one of the plurality of board junction pads by penetrating the base film.

14. The method as claimed in claim 9, wherein (a) comprises forming a solder resist layer on the second surface of the base film.

15. A multi-chip package comprising:
a tape circuit board having a base film, a plurality of ball land pads, and a plurality of board junction pads, wherein a chip mounting area is located on a first surface of the base film, the plurality of ball land pads are formed on a second surface of the base film, and the plurality of board junction pads are electrically connected to an associated one of the plurality of ball land pads by a circuit routing means;
a first semiconductor chip mounted to the chip mounting area of the first surface of the base film using an adhesive;
a second semiconductor chip mounted on the first semiconductor chip using an adhesive;
a plurality of bonding wires electrically connecting the first and second semiconductor chips with a corresponding one of the plurality of board junction pads;
a package body encapsulating the first and second semiconductor chips, the plurality of bonding wires, and conjunction portions of the bonding wires; and
a plurality of external contact terminals, each one formed to a corresponding one of the plurality of ball land pads.

16. The multi-chip package as claimed in claim 15, wherein the plurality of board junction pads are formed on the second surface of the base film in an area outside of the chip mounting area; and
a plurality of through holes for exposing predetermined portions of the plurality of board junction pads are formed through the base film, wherein each one of the plurality of chip pads and an associated one of the plurality of board junction pads are wire-bonded together through an associated through hole.

17. The multi-chip package as claimed in claim 15, wherein the plurality of board junction pads are formed on the first surface of the base film, and a plurality of via holes for electrically connecting one of the plurality of board junction pads and a corresponding one of the plurality of ball land pads are formed through the base film.

18. The multi-chip package as claimed in claim 15, wherein the plurality of ball land pads are formed within the chip mounting area.

19. The multi-chip package as claimed in claim 15, wherein the plurality of ball land pads are isolated from the adhesive by the base film.

20. The multi-chip package as claimed in claim 15, wherein each one of the plurality of external contact terminals is a solder ball.

21. The multi-chip package as claimed in claim 15, wherein a solder resist layer is formed on the second surface of the base film.

22. The multi-chip package as claimed in claim 15, wherein the first and the second semiconductor chips are attached so that a plurality of chip pads formed on each of the first and the second semiconductor chips are away from the tape circuit board.
